(19) United States
(12) Patent Application Publication
(10) Pub. No.: US 2023/0416907 A1
(43) Pub. Date: Dec. 28, 2023

(54) PROCESS FOR MANUFACTURING SILICON-CONTAINING MATERIALS

(71) Applicant: WACKER CHEMIE AG, Munich (DE)

(72) Inventors: Michael FRICKE, Burghausen (DE); Moritz BECKER, Burghausen (DE); Claudia KLEINLEIN, Burghausen (DE); Jürgen PFEIFFER, Mehring (DE); Sebastian SUCKOW, Burghausen (DE)

(73) Assignee: Wacker Chemie AG, Munich (DE)

(21) Appl. No.: 18/037,365

(22) PCT Filed: Nov. 30, 2020
(86) PCT No.: PCT/EP2020/083899

§ 371 Date: May 17, 2023

(51) Int. Cl. C23C 16/24; C23C 16/442; C23C 16/04; C23C 16/44; C23C 16/455; H01M 4/36; H01M 4/38; H01M 4/587; C01B 33/02; C01B 33/04

(52) U.S. Cl. CPC C23C 16/24; C23C 16/442; C23C 16/045; C23C 16/4417; C23C 16/45523; H01M 4/366; H01M 4/386; H01M 4/587; C01B 33/02; C01B 33/043; H01M 2004/027

(57) ABSTRACT

Silicon-containing materials along with process for producing and uses for the same. The process includes reacting the silicon-containing materials in a fluidized bed reactor by deposition of silicon from at least one silicon precursor in pores and on the surface of porous particles. A fluidizing gas stream is provided within the fluidized bed reactor that is fully or partly induced to oscillate in a pulsed manner and propagates in the form of a wave and acts on the fluidized bed so as to form a homogeneously fluidized bed as a pulsed gas stream so as to form a homogeneously fluidized bed having a fluidization index FI of at least 0.95. Where the fluidizing gas stream has a superficial velocity which is above a measured minimum fluidization velocity of the pulsed gas stream and where the pulsation is combined with mechanical stirring as a further fluidizing aid.

The invention relates to a process for producing silicon-containing materials in a fluidized bed reactor by deposition of silicon in pores and on the surface of porous particles, and to the use of the silicon-containing materials thus obtained as active materials for anodes of lithium ion batteries.

As storage media for electrical power, lithium ion batteries are currently the practicable electrochemical energy storage medium that has the highest energy densities. Lithium ion batteries are used particularly in the field of portable electronics, for tools, and also for electrically driven modes of transport, such as motorcycles, mopeds or automobiles. A widespread active material for the negative electrode (“anode”) corresponding batteries is currently graphitic carbon. A disadvantage, however, is a relatively low electrochemical capacity of such graphitic carbons, which is theoretically only a maximum of 372 mAh per gram of graphite and hence corresponds only to about one tenth of the electrochemical capacity theoretically achievable with lithium metal. Alternative active materials for the anode use an addition of silicon, as described, for example, in EP 1730800 B1, U.S. Pat. No. 10,559,812 B2, U.S. Pat. No. 10,819,400 B2, or EP 3335262 B1. Silicon forms binary electrochemical reactive alloys with lithium, which enable very high electrochemically achievable lithium contents of up to 3579 mAh per gram of silicon [M. Obrovac, V. L. Chevrier Chem. Rev. 2014, 114, 11444].

The intercalation and deintercalation of lithium ions into silicon is associated with the disadvantage that a very significant change in volume occurs, which can reach up to 300% in the case of complete intercalation. Such changes in volume subject the silicon-containing active material to significant mechanical stress, on account of which the active material can ultimately break up. This process, also referred to as electrochemical grinding, leads to a loss of electrical contact in the active material and in the electrode structure, and hence to a lasting, irreversible loss of electrode capacity.

Moreover, the surface of the silicon-containing active material reacts with constituents of the electrolyte with continuous formation of passivating protective layers (solid electrolyte interphase; SEI). The component phases formed are no longer electrochemically active. The lithium bound therein is no longer available to the system, which leads to a marked continuous loss of battery capacity. Because of the extreme change in volume of the silicon during the charging and discharging procedure of the battery, the SEI regularly breaks up, as a result of which further, as yet uncovered surfaces of the silicon-containing active material are exposed, which are then subject to further SEI formation. Since the amount of mobile lithium, corresponding to the usable capacity, in the full cell is limited by the cathode material, this is consumed to an increasing degree, and the capacity of the cell falls to a degree which is unacceptable for application purposes even after a few cycles.

The decrease in capacity over the course of multiple charging and discharging cycles is also referred to as fading or continuous loss of capacity, and is generally irreversible.

Active materials that have been described for anodes of lithium ion batteries are a number of silicon-carbon composite particles in which the silicon is intercalated into porous carbon particles proceeding from the gaseous or liquid silicon precursors. The intercalation process is also referred to as deposition or filtration, and can be effected in a gas-fluidized bed, for example, in U.S. Pat. No. 10,508,335 B1.

It is common knowledge that gas-fluidized beds are of excellent suitability for gas-solid reactions and hence also for the process of intercalation of silicon into porous particles.

In a gas-fluidized bed, a bed of solid particles is loosened and borne by a gas flowing upward to such an extent that the layer of solids shows liquid-like characteristics as a whole [VDI-Wärmeatlas [VDI Heat Atlas], 11th edition, section L3.2 Strömungsformen and Druckverlust in Wirbelschichten [Types of Flow and Pressure Drop in Fluidized Beds], p. 1371-1382, Springer Verlag, Berlin Heidelberg, 2013].

Gas-fluidized beds are generally also referred to as fluidized beds. The operation of creating a fluidized bed is also referred to as fluidization or fluidizing.

In a gas-fluidized bed, the solid particles are very well-dispersed. Consequently, a very high contact area forms between solids and gas, which can be utilized in an ideal manner for energy and mass transfer processes. Gas-fluidized beds are generally characterized by very good mass and heat transfer operations and by a uniform temperature distribution. The quality of the mass and heat transfer processes is crucial especially for the homogeneity of products obtained by reactions in fluidized beds, and can be correlated with the homogeneity of the fluidization state. A homogeneous fluidized bed, or the homogeneity of the fluidization state, by comparison with an inhomogeneous fluidized bed or an inhomogeneous fluidization state, is characterized by higher local heat transfer, by a smaller temperature differential in the fluidized bed, by short mixing times of two different particle collectives with similar particle size and particle density, by a smaller proportion of suspended particles, and by a smaller proportion of domains in the fluidized bed through which there is no flow.

Multiple methods are known for assessment of the homogeneity of the fluidization state of a gas-fluidized bed. For example, the fluidization state can be described by the dimensionless fluidization index FI, which expresses the measured pressure drop across the entire fluidized bed as a ratio with maximum pressure drop theoretically achievable with a fully formed fluidized bed, with a maximum value of 1 being obtained for the fluidization index for a fully fluidized bed [Bizhaem, Hamed K.; Tabrizi, Hassan B.: Experimental study on hydrodynamic characteristics of gas-solid pulsed fluidized bed. In: Powder Technology 237 (2013), p. 14-23.]. In practical execution, as a result of measurement accuracy, calculated values for FI can be slightly above 1. A further means of assessing the fluidization state is the measurement of local heat transfer between any surface of a component within the fluidized bed and the fluidized bed itself. The magnitude of the coefficient of heat transfer correlates with the homogeneity of the fluidization state of the fluidized bed [Baerns, M.: Effect of interparticle adhesive forces on fluidization of fine particles. In: Industrial & Engineering Chemistry Fundamentals 5 (1966), no. 4, p. 508-516].

The fluidization properties can be classified depending on the particle size and solid-state density of the particles. Particles having a particle size d₅₀<20 μm and having a density differential between particles and gas >100 kg/m³ are covered by Geldart class C (cohesive) [Geldart, D.; Types of Gas Fluidization, Powder Technol., 7, 1973, 285-292]. Particles of Geldart class C are characterized in that they are difficult to convert to a fluidized state. On account of their small particle size, the influence of interparticulate attraction forces is in the same order of magnitude or greater than the forces that act on the primary particles via the flow of gas. Correspondingly, effects such as the lifting of the fluidized bed as a whole and/or channel formation occur. In the case of channel formation, rather than a fluidized bed, tubes form in the particle bed, through which the fluidizing gas flows preferentially, while there is no flow at all through the majority of the bed. As a result, no homogeneity of fluidization is achieved. If the gas velocity is increased well above the minimum fluidization velocity of the primary particles of the bed, agglomerate consisting of individual particles form with time, and these can be fully or partly fluidized. Typical behavior is the formation of layers with agglomerates of different size. In the lowermost layer, directly above the inflow base, there are very large agglomerates that are moved very little, if at all. In the layer above, there are smaller fluidized agglomerates. The smallest agglomerates are present in the uppermost layer, and these are partly entrained by the gas flow, which is problematic from an engineering point of view. The fluidization characteristics of such particle beds are additionally characterized by formation of large gas bubbles and small expansion of the fluidized bed. In the English-language literature, this behavior is referred to as “agglomerate bubbling fluidization” (ABF). [Shabanian, J.; Jafari, R.; Chaouki, J., Fluidization of Ultrafine Powders, IRECHE., vol. 4, N.1, 16-50].

It will be clear to the person skilled in the art that ABF fluidized beds, on account of the inhomogeneities within the fluidized bed and the associated inhomogeneous mass and heat transfer conditions, are unsuitable for the production of substances having homogeneous properties.

There are known fluidizing aids in order to convert particles of Geldart class C in the form of agglomerates to a predominantly homogeneous fluidized bed. U.S. Pat. No. 7,658,340 B2 describes, for example, the introduction of further force components such as vibration forces, magnetic forces, acoustic forces, rotary or centrifugal forces or combinations thereof, as well as the force applied by the fluidizing gas, to influence the size of the agglomerates consisting of SiO₂ nanoparticles (Geldart class C) in the fluidized bed so as to form a predominantly homogeneous fluidized bed. The homogeneity of the fluidized bed is assessed visually by the mixing of colored and uncolored particles and via the fluidization index. The homogeneous fluidized bed is characterized by a fluidization index close to 1, by distinct bed expansion, by a homogeneous appearance, by low particle discharge, and by short mixing times of 2 minutes.

A further means of fluidization of particles of Geldart class C is the input of a pulsating fluidizing gas stream. Akhavan et al. [Akhavan, A.; Rahman, F.; Wang, S.; Rhodes, M.; Enhanced fluidization of nanoparticles with gas phase pulsation assistance, Powder Technol., 284, 2015, 521-529] describe the effect of a pulsating fluidizing gas stream on the fluidization properties of SiO₂ and TiO₂ particles (Geldart class C and ABF characteristics) in fluidized beds. The homogeneity of the fluidization was assessed visually and by measurement of pressure drop. The use of gas, and destroyed the gas channels, and cause the fluidized bed to be converted to a visually homogeneous state with distinctly greater bed expansion than without pulsation. With the aid of pressure drop measurement, it was possible to show that the complete particle bed had been converted to the fluidized bed. Moreover, it was found that fluidization with pulsation sets in even at smaller minimum fluidization velocities than without pulsation.

Cadoret et al. [Cadoret, L.; Reuge, N.; Pannala, S.; Syamlal, M.; Rossignol, C.; Dexpert-Ghys, J.; Coufort, C.; Caussat, B.; Silicon Chemical Vapor Deposition on macro and submicron powders in a fluidized bed, Powder Technol., 190, 185-191, 2009] describe the deposition of silicon from monosilane SiH₄ onto nonporous titanium oxide particles of sub-micrometer size (Geldart class C) in a vibrating fluidized bed reactor. The aim of the study was to uniformly coat the TiO₂ particles without bearing the particle size of the primary particles. The vibration input limited the agglomerates to the size range of 300 to 600 μm in the fluidized bed. Pressure drop measurements showed that the complete particle bed was fluidized during the coating reaction. Homogeneous reaction conditions throughout the fluidized bed reactor were demonstrated by electron micrographs on uniformly coated particles that were removed at different sites in the fluidized bed reactor. Vibrating systems are disadvantageous in relation to the economic viability of the process, since vibrations have an adverse effect on the strength of the reactor materials, which leads to shortened lifetimes of the apparatuses. Also disadvantageous is the rising complexity of the execution of a vibrating fluidized bed reactor in terms of scaling, and the assurance of the integrity of such a fluidized bed reactor, which is important from a safety point of view, with use of highly reactive gases, as required for the deposition of silicon from gaseous silicon precursors in porous particles.

U.S. Pat. No. 10,668,499 B2 describes a method of applying a surface coating of Geldart class C particles, which may also be porous, in a fluidized bed reactor, wherein the oscillating fluidizing gas stream is modulated so as to form a standing wave of the gas stream. The standing wave results in uniform distribution of the particles in the fluidized bed reactor. At the same time, the use of the standing wave makes it possible to deposit thin layers on the surface in uniform distribution over all particles. In order to create a standing wave, it is necessary to incorporate a reflector in the fluidized bed reactor, which must be partly permeable to the reaction gas. Under reactive conditions in a deposition process, such reactor internals are highly disadvantageous since the material being deposited can likewise be deposited on the reflector, which reduces gas permeability with increasing process time to the extent of complete blockage of the fluidized bed reactor.

U.S. Pat. No. 10,508,335 B1 describes a fluidized bed method for deposition of silicon from SiH₄ in porous carbon matrices. In this case, however, particles having a particle size of d₅₀>50 μm are used in the fluidized bed method, in order to avoid the formation of large agglomerates consisting of primary particles, since agglomerate formation firstly produces an in homogeneous fluidized bed, which leads to a homogeneous reaction conditions at the reactor level, and, at the same time, the slow mass transfer within the agglomerate likewise results in inhomogeneous reaction conditions at the agglomerate level. A disadvantage of the method described is that the materials obtained, for use in anode materials for lithium ion batteries, have to be brought to the required size of <20 μm by grinding in a complex further step. In this additional step, material is additionally lost, which greatly restricts the economic attractiveness of the method.

Against this background, the problem addressed was that of providing a technically easily implementable process for the production of silicon-containing materials by deposition of silicon in pores and on the surface of porous particles by means of thermal breakdown of at least one silicon precursor in a fluidized bed reactor with sufficiently homogeneous fluidization, by which silicon-containing materials having high storage capacity for lithium ions are obtainable, which enable high cycling stability in use as active material in anodes of lithium ion batteries, which process avoids the disadvantages of the processes described in the prior art, especially in relation to inadequate homogeneity of the products.

It has been found that, surprisingly, the above-described problems with the prior art processes for the deposition of silicon from a silicon precursor into or onto porous particles can be solved effectively by conducting the deposition in a fluidized bed reactor with a fluidizing gas stream that has pulsating action on the fluidized bed in the form of a wave, so as to form a homogeneously fluidized bed characterized by a fluidization index of FI≥0.95. In a preferred embodiment, the homogeneously fluidized bed is characterized by a coefficient of heat transfer a between any surface of a component present in the fluidized bed and the fluidized bed itself, based on the maximum coefficient of heat transfer aₘₐₓ between any surface of a component present in the fluidized bed and the fluidized bed itself, of a/aₘₐₓ≥0.95.

It has additionally been found that, surprisingly, in the inventive deposition of silicon from a gaseous silicon precursor, even in the case of agglomerate formation in the fluidized bed, based on the internal porosity, it is possible to produce homogeneously infiltrated products both within the agglomerates and within the entire fluidized bed reactor.

The invention provides a process for producing silicon-containing materials in a fluidized bed reactor by deposition of silicon from at least one silicon precursor in pores and on the surface of porous particles, characterized in that a fluidizing gas stream propagates in the form of a wave through pulsation in the fluidized bed reactor and acts on the fluidized bed so as to form a homogeneously fluidized bed characterized by a fluidization index FI of at least 0.95. The fluidization index FI is thus generally selected from the range from 0.95 to 1.

In a preferred embodiment, the fluidized bed is characterized by a coefficient of heat transfer a between any surface of a component present in the fluidized bed and the fluidized bed itself, based on the maximum coefficient of heat transfer aₘₐₓ between any surface of a component present in the fluidized bed and the fluidized bed itself, of a/aₘₐₓ≥0.95.

It is generally the case that the primary particles of the porous particles, as fine particles, can be fluidized only with formation of agglomerates, if at all. It is therefore all the more surprising that the process of the invention results in uniform deposition of silicon in and on the porous particles. The silicon-containing materials thus obtained can advantageously be used as active material for anodes in lithium ion batteries and, because of the silicon deposited homogeneously in pores and on the surface of the porous particles, enable the provision of lithium ion batteries having very high cycling stability.

The process of the invention preferably includes the following phases:
Phase 1: filling the fluidized bed reactor with porous particles,
Phase 2: fluidizing the porous particles with at least one inner gas as fluidizing gas and adjusting the temperature of the fluidized bed reactor to the temperature for the conversion in phase 3,
Phase 3: fluidizing with at least one inner gas as fluidizing gas with addition of reactive gas containing one or more silicon precursors and converting the silicon precursors were deposition of silicon in pores and on the surface of the porous particles,
Phase 4: cooling the fluidized bed reactor and fluidizing with at least one inert gas as fluidizing gas,
Phase 5: removing the reaction products from the fluidized bed reactor.

In phase 1, porous particles are filled into a fluidized bed reactor.

In phase 2, the porous particles, generally also called “particle bed”, are fluidized and generally simultaneously purged by supply of at least one inert gas. Inert gases selected are preferably gases or gas mixtures selected from the group comprising hydrogen, helium, neon, argon, nitrogen and forming gas, particular preference being given to the use of nitrogen or argon. The inert gas constituent of the fluidizing gas is preferably present in an amount of at least 50%, more preferably at least 90% and most preferably at least 99%, based on the partial pressure of the inert gas constituents in the total pressure of the fluidizing gas under standard conditions (to DIN 1343).

The process is more particularly characterized in that the fluidizing gas stream propagates in the form of a wave through pulsation in the fluidized bed reactor or, for example, in other words, is induced to oscillate in a pulsed manner. Advantageously, the transmission of the gas oscillation to the fluidized bed makes it possible to avoid the disadvantageous fluidization characteristics of Geldart class C particles. The fluidizing gas stream may, for example, be set fully or partly in pulsation. The ratio of pulsed fluidizing gas substream to the overall fluidizing gas stream, where the overall fluidizing gas stream is composed of a pulsed and non-pulsed fluidizing gas substream, is within a range from preferably 0.1 to 1, more preferably between 0.3 and 1 and especially preferably between 0.5 and 1. The oscillation may be induced, for example, in the form of square profiles, triangular profiles, sawtooth profiles, sinusoidal profiles or in any combinations thereof. The frequency of the oscillation, given by the reciprocal of the period duration, is preferably within a range from 0.1 to 20 Hz, preferably between 0.5 and 10 Hz and more preferably between 0.5 and 6 Hz. The duty factor, which describes the ratio of pulse duration to period duration, is preferably within a range from 0.1 to 0.9, more preferably from 0.2 to 0.8. The inducement oscillation is preferably periodic with constant frequency, pulse shape and duty factor. In a further preferred embodiment, the fluidizing gas stream is made to oscillate with frequency and/or pulse shape and/or duty factor that are variable over time. The pulse fluidizing gas stream preferably passes through a gas-permeable base into the fluidized bed reactor. Unwanted effects such as channel formation or uncontrolled agglomerate growth may be prevented, for example, by adjusting the fluidizing gas stream, preferably instantly, to values within the preferred working range.

The process is preferably conducted with fluidizing gas streams having superficial velocities above the measured minimum fluidization velocity of the pulsed gas stream. The preferred working range is at values between 1 and 10 times the measured minimum fluidization velocity, preferably between 2 and 8 times the measured minimum fluidization velocity, and more preferably between 2 and 5 times the measured minimum fluidization velocity.

The process is also characterized in that fluidization state of the fluidized bed is characterized by the dimensionless fluidization index FI≥0.95. The fluidization index FI is defined as the ratio of the measured pressure drop across the fluidized bed Δp_{WS,measured} and the theoretically maximum achievable pressure drop P_{WS,th} and is calculated by the following equation:

$$F I = \frac{Δ {p}_{WS , measured}}{Δ {p}_{WS , th}}$$

The theoretically maximum achievable pressure drop is calculated, neglecting the gas density, from the mass of the bed m_{S}, the acceleration due to gravity g and the cross-sectional reactor area A_{WS} as Δp_{WS,th}=m_{S}·g/A_{WS}. The other parameters for determination of the fluidization index can be found further down at the start of the description of the examples.

The process is preferably characterized in that the coefficient of heat transfer a between any surface of a component present in the fluidized bed and the fluidized bed itself, based on the maximum coefficient of heat transfer ax between any surface of a component present in the fluidized bed and the fluidized bed itself, is characterized by a/aₘₐₓ≥0.95.

As well the fluidization, in phase 2, the temperature of the fluidized bed reactor is adjusted, with continuing pulsed supply of at least one fluidizing gas, to the temperature for the reaction in phase 3.

The conversion in phase 3 refers generally to the breakdown of the silicon precursors with deposition of silicon in the pores and on the surface of the porous particles.

In phase 3, especially after attainment of the temperature for the deposition of silicon, the fluidization of the fluidized bed is generally continued by pulsed supply of at least one inert gas and supply of a reactive gas to the fluidized bed. The reactive gas is preferably supplied as a partial to complete addition to the inert gas stream or, in other words, as a constituent of the fluidizing gas or elsewhere in the reaction space independently of the fluidizing gas.

The inert gas constituent of the fluidizing gas is preferably present in an amount of at least 50% based on the partial pressure of the inert gas constituents in the total pressure of the fluidizing gas under standard conditions (to DIN 1343).

The reaction temperature or temperature for the deposition of silicon is in the range from preferably 100 to 1000° C., more preferably in the range from 300 to 900° C. and especially preferably in the range from 380 to 750° C.

The deposition of silicon is effected within a pressure range between preferably 0.1 and 5 bar, more preferably at atmospheric pressure.

The supply of reactive gas preferably essentially does not change the fluidization state. The fluidized bed is still characterized by a fluidization index FI≥0.95. In a further embodiment, the fluidized bed is preferably characterized by the coefficient of heat transfer a between any surface of a component present in the fluidized bed and the fluidized bed itself, based on the maximum coefficient of heat transfer aₐ between any surface of a component present in the fluidized bed and the fluidized bed itself, given optimal fluidization of the fluidized bed at a given fluidizing gas temperature and composition, of a/aₘₐₓ≥0.95.

The reactive gases used in phase 3 contain at least one or more than one silicon precursor. As well the silicon precursors, the reactive gases may contain inert gases. The reactive gases preferably contain >50%, more preferably >80% and especially preferably >90% inert gas based on the partial pressure of the inert gas in the total pressure of the reactive gas under standard conditions (DIN 1343).

The silicon precursor generally contains at least one reactive constituent that can generally react to give silicon under thermal treatment. The reactive constituent is preferably selected from the group comprising silicon-hydrogen compounds, for example monosilane SiH₄, disilane Si₂H₆ and higher linear, branched or else cyclic homologs, neopentasilane Si₅H₁₂, cyclo-hexasilane Si₆H₁₂, chlorinated silanes, for example trichlorosilane HSiCl₃, dichlorosilane H₂SiCl₂, chlorosilane H₃SiCl, tetrachlorosilane SiCl₄, hexachlorodisilane Si₂Cl₆, and higher linear, branched or else cyclic homologs, for example 1,1,2,2-tetrachlorodisilane Cl₂HSi—SiHCl₂, chlorinated and partly chlorinated oligo- and polysilanes, methylchlorosilanes, for example trichloromethylsilane MeSiCl₃, dichlorodimethylsilane Me₂SiCl₂, chlorotrimethylsilane Me₃SiCl, tetramethylsilane Me₄Si, dichloromethylsilane MeHSiCl₂, chloromethylsilane MeH₂SiCl, methylsilane MeH₃Si, chlorodimethylsilane Me₂HSiCl, dimethylsilane Me₂H₂Si, trimethylsilane Me₃SiH or else mixtures of the silicon compounds described.

Particularly preferred reactive constituents are selected from the group comprising monosilane SiH₄, oligomeric or polymeric silanes, especially linear silanes of the general formula SiₙHₙ₊₂ where n may comprise an integer in the range of 2 to 10, and cyclic silanes of the general formula —[SiH₂]ₙ— where n may comprise an integer in the range of 3 to 10, trichlorosilane HSiCl₃, dichlorosilane H₂SiCl₂ and chlorosilane H₃SiCl, where these may be used on their own or as mixtures, very particular preference being given to using SiH₄, HSiCl₃ and H₂SiCl₂ on their own or in a mixture.

In addition, the reactive gases may contain further constituents, for example dopants based on boron-, nitrogen-, phosphorus-, arsenic-, germanium-, iron- or else nickel-containing compounds. The dopants are preferably selected from the group comprising ammonium NH₃, diborane B₂H₆, phosphine PH₃, germane GeH₄, arsane AsH₃ and nickel tetracarbonyl Ni(CO)₄.

During phase 3, the temperature may generally be kept constant or be varied by heating or cooling. Preference is given to the substantially spatially uniform conversion of the silicon precursor in pores and on the surface of porous particles, especially in order to obtain material having homogeneous properties.

It is possible to use different technical solutions in order to control the reaction rate of the conversion of the silicon precursors in phase 3. Preference is given to increasing or reducing the supply of heat in the fluidized bed reactor. This can, for example, increase or reduce the conversion. The removal of heat from the fluidized bed reactor is preferably enhanced by cooling, in which case, for example, one or more reactor walls are cooled or devices for removal of heat, for example coolable plates, tubes or tube bundles, are introduced into the fluidized bed reactor. For example, this can reduce the reaction rate. More preferably, the reactive gas composition is altered in order to very rapidly control the reaction rate.

The progression of the conversion of reactive gas in phase 3 is preferably monitored analytically. In this way, it is possible, for example, to recognize the attainment of the desired amount of deposited silicon and hence to minimize the reactor occupation time. Such methods preferably include temperature measurement, for example to determine exo- or endothermicity, pressure measurements, for example to ascertain the progression of the conversion via varying ratios of solid to gaseous constituents of the reactor contents, and further methods that enable, for example, the observation of the varying composition of the gas space during the conversion of reactive gas.

In a further preferred embodiment, in phase 3, especially after the desired dwell time, a proportion of the silicon-containing material formed is removed from the fluidized bed reactor, while porous particles are replenished, more preferably with replenishment of an amount of porous particles corresponding to a proportion of silicon-containing material removed. At the desired dwell time, sufficient conversion of the silicon precursors or sufficient deposition of silicon in or on the porous particles has been attained. This juncture may be ascertained, for example, by gas chromatography analysis of the gas stream leaving the fluidized bed reactor.

In phase 4, preferably after the conversion of reactive gas has ended, the fluidizing gas, for pulsed fluidization of the fluidized bed reactor, is switched to a gas stream comprising inert gas, more preferably pure inert gas. In this way, it is possible, for example, to eliminate reactive constituents from the fluidized bed reactor. Constituents of the inert gas stream used are preferably inert gases selected from the group comprising hydrogen, helium, neon, argon or nitrogen, or forming gas, optionally with addition of air. Particular preference here is given to nitrogen, argon or air, or mixtures thereof. Preference is given to simultaneously cooling the temperature of the fluidized bed reactor to a desired lower temperature, more preferably 20 to 50° C., especially preferably 20 to 30° C.

In a specific embodiment, the fluidized bed reactor is purged. The purging is preferably effected with a mixture comprising inert gas and oxygen. This mixture preferably contains not more than 20% by volume, more preferably not more than 10% by volume and especially preferably not more than 5% by volume of oxygen. The temperature here is preferably not more than 200° C., more preferably not more than 100° C. and especially preferably not more than 50° C. In this way, it is possible, for example, to modify, for example deactivate, the surface of the silicon-containing material. For example, it is possible to achieve reaction of any reactive groups present on the surface of the silicon-containing material.

In phase 5, reaction products, especially the silicon-containing material, are removed from the fluidized bed reactor, optionally with retention of an inert gas atmosphere in the fluidized bed reactor.

The temperature, the pressure or measurements of pressure differential in the fluidized bed reactor may be determined with measuring devices and by test methods that are standard for fluidized bed reactors. After customary calibration, different measuring devices give the same measurement results.

In a preferred embodiment, the sequence of phases 2 to 4 is performed repeatedly. It is particularly preferable here that no particles that form the fluidized bed are removed from the fluidized bed reactor. It is possible here for the silicon precursors used in the respective phase 3 to be the same or different. It is possible here to dispense with phase 4 in one or more sequences. Phase 4 as well is preferably executed in the sequence conducted last.

In a further preferred embodiment, the sequence of phases 2, 3 and optionally 4, i.e. optionally dispensing with phase 4, is performed repeatedly, in which case it is also possible to use silicon precursor-free reactive gases in phase 3 in one or more of the sequences, where the silicon precursor-free reactive gases may generally be the same or different in the respective sequences, with the proviso that a reactive gas containing a silicon precursor is used in at least one sequence. Silicon precursor-free reactive gases generally do not contain any silicon precursor. The silicon precursor-free reactive gas is preferably contain one or more hydrocarbons. In this specific embodiment, silicon precursor-free reactive gas can be effected in a sequence before or after the deposition of silicon or else between two depositions of silicon.

In a preferred specific embodiment, in the case of repeated execution of the sequence of phases 2, 3 and optionally 4, in the first sequence, a silicon precursor-containing reactive gas is used in phase 3 and, in a second sequence, a hydrocarbon-containing, silicon precursor-free reactive gas is used in phase 3. It is preferably possible here to dispense with phase 4 in the first sequence. These embodiments afford a silicon-containing material having no outward silicon surface.

In a further preferred specific embodiment, in the case of multiple execution of the sequence of phases 2, 3 and optionally 4, in the first sequence, a hydrocarbon-containing, silicon precursor-free reactive gas is used in phase 3 and, in the second sequence, a silicon precursor-containing reactive gas. Optionally, in a third sequence, a further hydrocarbon-containing, silicon precursor-free reactive gas may be used in phase 3. In this case, it is possible to dispense with phase 4 in the first sequence after phase 3 and/or in the second sequence after phase 3. In this way, it is possible, for example, to obtain a silicon-containing material which has a carbon layer between the porous particles and the deposited silicon and which optionally additionally bears an outer carbon layer, as a result of which there is no outward silicon surface.

Examples of silicon precursor-free reactive gases that may be used include any gases or mixtures of gases that can be converted to solids by increasing the temperature. Examples of these are hydrocarbons selected from the group comprising aliphatic hydrocarbons having 1 to carbon atoms, especially 1 to 6 carbon atoms, preferably methane, ethane, propane, butane, pentane, isobutane, hexane, cyclopropane, cyclobutane, cyclopentane, cyclohexane and cycloheptane, unsaturated hydrocarbons having 1 to 10 carbon atoms, such as ethene, acetylene, propene or butene, isoprene or butadiene, divinylbenzene, vinylacetylene, cyclohexadiene, cyclooctadiene, cyclic unsaturated hydrocarbons such as cyclopropene, cyclobutene, cyclopentene, cyclohexene, cyclohexadiene, cyclopentadiene, dicyclopentadiene or norbornadiene, aromatic hydrocarbons such as benzene, toluene, p-, m-, o-xylene, styrene (vinylbenzene), ethylbenzene, diphenylmethane or naphthalene, further aromatic hydrocarbons such as phenol, o-, m-, p-cresol, cymene, nitrobenzene, chlorobenzene, pyridine, anthracene, phenanthrene, myrcene, geraniol, thioterpineol, norbornane, borneol, isoborneol, bornane, camphor, limonene, terpinene, pinene, pinane, carene, phenol, aniline, anisole, furan, furfural, furfuryl alcohol, hydroxymethylfurfural or bishydroxymethylfuran and mixed fractions that contain a multitude of such compounds, for example from natural gas condensate, mineral oil distillate, coking furnace condensates, mixed fractions from the product streams of a fluid catalytic cracker (FCC), steamcracker or a Fischer-Tropsch synthesis plant, or quite generally hydrocarbon-containing streams of matter from the processing of wood, natural gas, mineral oil and coal.

The hydrocarbon-containing, silicon precursor-free reactive gases may contain one hydrocarbon or else mixtures of two or more hydrocarbons. The hydrocarbon-containing, silicon precursor-free reactive gases may be used without further components or as a mixture with inert gases or else other reactive gases such as hydrogen. In addition, the hydrocarbon-containing, silicon precursor-free reactive gases may also contain other reactive components, for example dopant is based on boron-, nitrogen-, phosphorus-, arsenic-, germanium-, iron- or else nickel-containing compounds. The dopants are preferably selected from the group comprising ammonia NH₃, diborane B₂H₆, phosphine PH₃, germane GeH₄, arsane AsH₃ and nickel tetracarbonyl Ni(CO)₄.

Fluidized bed reactors used may be any of the designs known to the person skilled in the art. As usual, the region of the fluidized bed reactor starts from a gas-permeable base in which the bed, for example comprising porous particles, is fluidized and hence the fluidized bed is formed.

The gas-permeable base is also referred to as gas distributor base or inflow base. Examples of these are porous plates, perforated plates, nozzle trays, bubble-cap trays, manufacturer-specific or proprietary designs, or combinations thereof. It is possible, for example, to introduce the inert component of the fluidizing gas into the fluidized bed reactor via one type of tray and the reactive gas as an addition or proportion of the fluidizing gas via another type of tray. In a preferred embodiment, the reactive gas is mixed into the fluidizing gas and, as a constituent thereof, produces the fluidized bed therewith. In a further embodiment, the reactive gas is fed into the reaction space in particular nozzles in the base plate parallel to the fluidizing gas. In a further preferred embodiment, the reactive gas is fed into the fluidized bed reactor at a different site removed from the base plate, for example in countercurrent.

If the reactive gas is fed in at least in portions via a baseplate of the fluidized bed reactor, it is preferable that the gas-permeable base is cooled down to temperatures below the reaction temperature. This can avoid reactions of the reactive gas with the surface of the gas-permeable base.

For the cross-sectional area of the fluidized bed reactor, circular, elliptical, square, rectangular, or generally convex polygonal embodiments are preferred. The shape of the fluidized bed reactor in which the bed is fluidized is preferably executed as a circular cylinder, elliptical cylinder or prism having any base area. Above the region in which the fluidized bed forms, there preferably follows a distinct widening of the cross-sectional area. Designs of this “calming zone” are preferably executed in analogous form to the region in which the fluidized bed is formed. Additionally preferred embodiments in which there is already a change in cross-sectional area in the region of the fluidized bed, where the cross-sectional area may be of any shape. In principle, the fluidized bed reactor may also be executed as a circulating fluidized bed.

The exit of the fluidizing gas from the fluidized bed reactor is preferably designed such that particles entrained with the flow are separated from the fluidizing gas stream. The particles are preferably removed by mechanical filtration, especially via filter cartridges, filter bags, filter pouches or filter hoses, or by means of electrostatic filters. A further preferred mode of deposition of solid particles from gas flows is effected by using gravitational separators such as cyclones or centrifugal sifters. Combinations such as the connection of a gravitational separator upstream of a mechanical filter, for example, are further preferred designs.

The filtration unit is preferably cooled down to temperatures below the silicon deposition temperature. In this way too, it is possible to avoid unwanted reactions between the reactive gas and the surface of the filtration material.

In order to generate pulsation of the fluidizing gas stream, preference is given to different ways of inducing oscillation in the fluidizing gas stream. The oscillation of the fluidizing gas stream is preferably generated via changes in pressure, more preferably via pneumatic and/or mechanical devices. The oscillation of the fluidizing gas is preferably generated by rapid changes in pressure of the fluidizing gas in the feed device upstream of the gas-permeable base, in the fluidized bed chamber itself and/or at the gas exit upstream or downstream of the filter, where the change in pressure is preferably generated via ventilators and/or shutoff valves. Thus, a valve in the gas feed is preferably opened and closed periodically. The periods of time for the open and closed position, for example, are used to adjust the pulsation frequency. A further preferred embodiment to the use of a rotating flap in the gas feed. For example, the pulsation frequency is varied by setting the speed of the rotating flap.

A preferred embodiment for generation of partly pulsed fluidizing gas streams is achieved by the control division of the gas stream in the gas feed to the fluidized bed reactor, with one of the gas streams being induced to oscillate. Both gas streams may be introduced independently into the fluidized bed reactor via the gas-permeable base or be mixed upstream of the gas-permeable base and introduced into the fluidized bed reactor as a mixture. The closed-loop control of the two gas streams allows the ratio of pulsed fluidizing gas stream to the overall fluidizing gas stream to be fixed.

The process temperature can be controlled, for example, using heating or cooling devices. A preferred procedure is the preheating of the fluidizing gas in the feed to the fluidized bed reactor. The heat is preferably transferred by radiation and convection. This preheating is preferably effected by means of electrical flow heaters, gas-fired flow heaters, steam-based flow heaters or combinations thereof. In order to establish the desired reaction temperature in the fluidized bed reactor, heating and cooling of the fluidized bed is preferred. The fluidized bed is preferably heated and cooled by the heat transfer mechanisms of radiation, particle convection and gas convection. Preferred executions for heating of heat transfer surfaces are radiative ovens with heating elements, gas firing, steam heating, heating by means of heat transfer oil (for example WACKER Helisol® with heating medium temperature to 425° C.), inductive heating or resistance heaters. The thermal energy is preferably exchanged between the heat transfer surface and the fluidized bed by irradiation, particle convection and gas convection. The fluidized bed is preferably also heated by direct radiation, for example infrared sources or microwaves. A further preferred embodiment for heating of the fluidized bed is the direct inductive heating of the fluidized bed.

The reactor cooling is preferably implemented by heat transfer to flowing cooling media, where the cooling media may preferably be in liquid form or may be both liquid and gaseous by virtue of boiling. The heat transfer surfaces for the heating and cooling are preferably implemented by the reactor walls and by internals of any shape and size in the fluidized bed, for example tubes, tube bundles, or plates through which fluid flows.

A further preferred embodiment of the combination of pulsation of the fluidizing gas with further fluidizing aids. For example, the fluidized bed generated by pulsation of the fluidizing gas may additionally be moved mechanically by a stirring unit. Additionally preferred is superposition of the pulsation of the fluidizing gas with a mechanical vibration of the fluidized bed reactor. Also preferred is the combination of pulsation of the fluidizing gas with the introduction of additional gas jets, which may be blown into the fluidized bed with a distinctly higher gas velocity.

For the construction of the fluidized bed reactor, any material is in principle usually any that has the necessary mechanical strength under the respective process conditions. With regard to chemical stability, the fluidized bed reactor may consist, for example, of corresponding pure materials or of chemically unstable materials (pressure-bearing) with specific coating or plating of parts in contact with media.

The materials for the fluidized bed reactors are preferably selected from the group comprising metallic materials which (according to DIN CEN ISO/TR 15608) for steels correspond to material groups 1 to 11, for nickel and nickel alloys to groups 31 to 38, for titanium and titanium alloys to groups 51 to 54, four zirconium and zirconium alloys to groups 61 and 62, and for cast iron to groups 71 to 76, ceramic materials composed of oxide ceramics in a single-material system, for example aluminum oxide, magnesium oxide, zirconium oxide, silicon dioxide, titanium dioxide (condenser material), and multimaterial systems, for example aluminum titanate (mixed form of aluminum oxide and titanium oxide), mullite (mixed form of aluminum oxide and silicon oxide), lead zirconate titanate (piezo ceramic), and dispersion ceramics, for example zirconia-toughened aluminum oxide (ZTA-Al₂O₃/ZrO₂) and nonoxide ceramics (carbides, for example silicon carbide, boron carbide; nitride, for example silicon nitride; aluminum nitride, boron nitride, titanium nitride; borides; silicides) and mixtures thereof, and composite materials that form part of the groups of particulate composites (for example cemented carbide, ceramic composites, concrete, polymer concrete), the fiber composites (for example glass fiber-reinforced glass, metal matrix composites (MMCs), fiber cement, carbon fiber-reinforced silicon carbide, intrinsically reinforced thermoplastics, steel-reinforced concrete, fiber concrete, fiber-polymer composites (for example carbon fiber-reinforced plastic (CFRP), glass fiber-reinforced plastic (GFRP), aramid fiber-reinforced plastic (AFK)), the fiber-ceramic composites (ceramic matrix composites (CMC)), the penetration composites or metal-matrix composites (MMCs) (for example dispersion-reinforced aluminum alloys or dispersion-hardened NiCr superalloys), the composite laminates (for example bimetals, TiGr composite, composite sheets and tubes, glass fiber-reinforced aluminum, sandwich constructions).

The process of the invention for production of silicon-containing materials offers various advantages over the prior art. A particular advantage is the generation of products having homogeneous properties in a single, efficiently scalable reaction step. Another advantage is the improvement in mass and heat transfer via the pulsation of the fluidizing gas stream. A further advantage is considered to be the control of the process by specific adjustment of reaction temperature and reactive gas composition, which can be varied during the process. Furthermore, the process regime enables periodic multiple depositions from the same or else from different silicon precursors all silicon precursor-free reactive gases. By virtue of these advantages, silicon-containing materials, especially for use as active material for anodes of lithium ion batteries having excellent properties, are rapidly and economically obtainable in an advantageous manner.

The porous particles are preferably selected from the group comprising amorphous carbon in the form of hard carbon, soft carbon, mesocarbon microbeads, natural graphite or synthetic graphite, single- and multiwall carbon nano to spend graphene, oxides selected from the group comprising silicon dioxide, aluminum oxide, mixed silicon-aluminum oxides, magnesium oxide, lead oxides and zirconium oxide, carbides selected from the group comprising silicon carbide and boron carbide, nitrides selected from the group comprising silicon nitrides and boron nitride, and other ceramic materials that can be described by the following component formula:
AlₐB_{b}C_{c}Mg_{d}NₑO_{f}Si_{g} with 0 £ a, b, c, d, e, f, g<1; with at least two coefficients a to g>0 and a*3+b*3+c*4+d*2+g*4³e*3+f*2.

The ceramic materials may, for example, be binary, ternary, quaternary, quinary, senary or septernary compounds. Preference is given to ceramic materials having the following component formulae:
nonstoichiometric boron nitrides BN_{z} with z=0.2 to 1,
nonstoichiometric carbon nitrides CN_{z} with z=0.1 to 4/3,
boron carbonitrides BₓCN_{z} with x=0.1 to 20 and z=0.1 to 20, where x*3+4³ z*3,
boron nitridooxides BN_{z}Oᵣ with z=0.1 to 1 and r=0.1 to 1, where 3³ r*2+z*3,
boron carbonitridooxides BₓCN_{z}Oᵣ with x=0.1 to 2, z=0.1 to 1 and r=0.1 to 1, where x*3+4³ r*2+z*3,
silicon carbooxides SiₓCO_{z} with x=0.1 to 2 and z=0.1 to 2, where x*4+4³ z*2,
silicon carbonitrides SiₓCN_{z} with x=0.1 to 3 and z=0.1 to 4, where x*4+4³ z*3,
silicon borocarbonitrides Si_{w}BₓCN_{z} with w=0.1 to 3, x=0.1 to 2 and z=0.1 to 4, where w*4+x*3+4³ z*3,
silicon borocarbooxides Si_{w}BₓCO_{z} with w=0.10 to 3, x=0.1 to 2 and z=0.1 to 4, where w*4+x*3+4³ z*2,
silicon borocarbonitridooxides SiᵥB_{w}CNₓO_{z} with v=0.1 to 3, w=0.1 to 2, x=0.1 to 4 and z=0.1 to 3, where v*4+w*3+4³ x*3+z*2 and
aluminum borosilicocarbonitridooxides AlᵤBᵥSiₓCN_{w}O_{z} with u=0.1 to 2, v=0.1 to 2, w=0.1 to 4, x=0.1 to 2 and z=0.1 to 3, where u*3+v*3+x*4+4³ w*3+z*2.

The porous particles preferably have a density, determined by helium pycnometry, of 0.1 to 7 g/cm³ and more preferably of 0.3 to 3 g/cm³. This is advantageous for increasing the gravimetric capacity (mAh/cm³) of lithium ion batteries.

The porous particles used are preferably amorphous carbon is, silicon dioxide, boron nitride, silicon carbide and silicon nitride, or mixed materials based on these materials, particular preference being given to the use of amorphous carbons, boron nitride and silicon dioxide.

The porous particles have a volume-weighted particle size distribution having diameter percentiles d₅₀ of preferably ≥0.5 μm, more preferably ≥1.5 μm and most preferably ≥2 μm. The diameter percentiles d₅₀ are preferably ≤20 μm, more preferably ≤12 μm and most preferably ≤8 μm.

The volume-weighted particle size distribution of the porous particles is preferably between the diameter percentiles d₁₀≥0.2 μm and d₉₀≤20.0 μm, more preferably between d₁₀≥0.4 μm and d₉₀≤15.0 μm and most preferably between d₁₀≥0.6 μm to d₉₀≤12.0 μm.

The porous particles have a volume-weighted particle size distribution with diameter percentiles d₁₀ of preferably ≤10 μm, more preferably ≤5 μm, especially preferably ≤3 μm and most preferably ≤2 μm. The diameter percentiles d₁₀ are preferably ≥0.2 μm, more preferably ≥0.5 and most preferably ≥1 μm.

The porous particles have a volume-weighted particle size distribution having diameter percentiles d₉₀ of preferably ≥4 μm and more preferably ≥10 μm. The diameter percentiles d₉₀ are preferably ≤18 μm, more preferably ≤15 and most preferably ≤13 μm.

The volume-weighted particle size distribution of the porous particles has a span d₉₀-d₁₀ of preferably ≤15.0 μm, more preferably ≤12.0 μm, particularly preferably ≤10.0 μm, especially preferably ≤8.0 μm and most preferably ≤4.0 μm. The volume-weighted particle size distribution of the porous particles has a span d₉₀-d₁₀ of preferably ≥0.6 μm, more preferably ≥0.8 μm and most preferably ≥1.0 μm.

The volume-weighted particle size distribution of the porous particles is determinable according to ISO 13320 by means of static laser scattering using the Mie model with the Horiba LA 950 measuring instrument with ethanol as dispersion medium for the porous particles.

The porous particles are preferably in the form of particles. The particles may, for example, be in isolated or agglomerated form. The porous particles are preferably not aggregated and preferably not agglomerated. What is generally meant by “aggregated” is that primary particles are formed at first in the course of production of the porous particles and coalesce, and/or primary particles are joined to one another, for example, via covalent bonds and in this way form aggregates. Primary particles are generally isolated particles. Aggregate or isolated particles can form agglomerates. Agglomerates are a loose coalition of aggregate or primary particles that are joined to one another, for example, via van der Waals interactions or hydrogen bonds. Agglomerated aggregates can easily be split up again into aggregates by standard kneading and dispersing methods. Aggregates can be divided into the primary particles only partly by these methods, if at all. The presence of the porous particles in the form of aggregates, agglomerates or isolated particles can be visualized, for example, by means of conventional scanning electron microscopy (SEM). Static light scattering methods for determining particle size distributions or particle diameters of matrix particles, by contrast, cannot distinguish between aggregates and agglomerates.

The porous particles may have any desired morphology, and may therefore, for example, be sputtery, platy, spherical or else acicular, with sputtery and spherical particles being preferred.

The morphology can be characterized, for example, by the sphericity W or the sphericity S. According to Wadell's definition, sphericity V is the ratio of the surface area of a sphere of equal volume to the actual surface area of a body. In the case of a sphere, the value of V is 1. According to this definition, the porous particles have a sphericity V of preferably 0.3 to 1.0, more preferably of 0.5 to 1.0 and most preferably of 0.65 to 1.0.

Sphericity S is the ratio of the circumference of an equivalent circle with the same area A as the projection of the particle projected onto a surface, to the measured circumference U of this projection: S=2\sqrt{πA}/U. In the case of a particle of ideal circularity, the value of S would be 1. For the porous particles, the sphericity S is in the range from preferably 0.5 to 1.0 and more preferably from 0.65 to 1.0, based on the percentiles S₁₀ to S₉₀ of the numerical sphericity distribution. The sphericity S is measured, for example, from optical micrographs of individual particles or preferably, in the case of particles <10 μm, with a scanning electron microscope, by graphic evaluation by means of image analysis software, such as ImageJ, for example.

The porous particles preferably have a gas-accessible pore volume of ≥0.2 cm³/g, more preferably ≥0.6 cm³/g and most preferably ≥1.0 cm³/g. This is useful for obtaining lithium ion batteries with a high capacity. The gas-accessible pore volume was determined by gas absorption measurements with nitrogen in accordance with DIN 66134.

The porous particles are preferably open-pore. Open-pore means generally that pores are connected to the surface of particles, via channels, for example, and can preferably be in mass transfer, especially in transfer of gaseous compounds, with the surroundings. This can be verified using gas absorption measurements (evaluation according to Brunauer, Emmett and Teller, “BET”), i.e., of the specific surface area. The porous particles have specific surface areas of preferably ≥50 m²/g, more preferably of ≥500 m²/g and most preferably ≥1000 m²/g. the BET surface area is determined according to DIN 66131 (with nitrogen).

The pores of the porous particles may have any desired diameters, i.e., generally, in the range of macropores (above 50 nm), mesopores (2-50 nm) and micropores (less than 2 nm). The porous particles can be used in any desired mixtures of different pore types. Preference is given to using porous particles having less than 30% of macropores, based on the total pore volume, more preferably porous particles without macropores, and very preferably porous particles with at least 50% of pores having a mean pore diameter of less than 5 nm. With very particular preference porous particles comprise exclusively pores having a pore diameter of less than 2 nm (method of determination: pore size distribution by BJH (gas adsorption) according to DIN 66134 in the mesopore range and according to Horvath-Kawazoe (gas adsorption) according to DIN 66135 in the micropore range; the evaluation of the pore size distribution in the macropore range is made by mercury porosimetry in accordance with DIN ISO 15901-1).

Preferred porous particles are those having a gas-inaccessible pore volume of less than 0.3 cm³/g and more preferably less than 0.15 cm³/g. In this way as well it is possible to increase the capacity of the lithium ion batteries. The gas-inaccessible pore volume may be determined by means of the following formula:

gas-inaccessible pore volume=1/pure-material density−1/skeletal density.

The pure-material density here is a theoretical density of the porous particles, based on the phase composition or the density of the pure material (the density of the material as if it had no closed porosity). Data on pure-material densities can be found by the skilled person in, for example, the Ceramic Data Portal of the National Institute of Standards (NIST, https://srdata.nist.gov/CeramicDataPortal/scd). For example, the pure-material density of silicon oxide is 2.203 g/cm³, that of boron nitride is 2.25 g cm³, that of silicon nitride is 3.44 g/cm³, and that of silicon carbide is 3.21 g/cm³. The skeletal density is the actual density of the porous particle (gas-accessible) determined by helium pycnometry.

For clarification it should be noted that the porous particles are different from the silicon-containing material. The porous particles act as starting material for producing silicon-containing material. There is preferably no silicon, more particularly no silicon obtained by deposition of silicon precursors, present in the pores of the porous particles and on the surface of the porous particles.

By the process of the invention, it is entirely surprisingly possible to fluidize the porous particles that belong to Geldart class C in a fluidized bed by means of the pulsating fluidizing gas stream.

The silicon-containing material obtained by means of deposition of silicon in the pores and on the surface of the porous particles has a volume-weighted particle size distribution with diameter d₅₀ preferably in a range from 0.5 to 20 μm. The d₅₀ value is preferably at least 1.5 μm, and more preferably at least 2 μm. The diameter percentiles d₅₀ are preferably at most 13 μm and more preferably at most 8 μm.

The volume-weighted particle size distribution of the silicon-containing material is situated preferably between the diameter percentiles d₁₀≥0.2 μm and d₉₀≤20.0 μm, more preferably between d₁₀≥0.4 μm and d₉₀≤15.0 μm, and most preferably between d₁₀≥0.6 μm to d₉₀≤12.0 μm.

The silicon-containing material has a volume-weighted particle size distribution with diameter percentiles d₁₀ of preferably ≤10 μm, more preferably ≤5 μm, especially preferably ≤3 μm and most preferably ≤1 μm. The diameter percentiles d₁₀ are preferably ≥0.2 μm, more preferably ≥0.4 μm and most preferably ≥0.6 μm.

The silicon-containing material has a volume-weighted particle size distribution with diameter percentiles d₉₀ of preferably ≥5 μm and more preferably ≥10 μm. The diameter percentiles d₉₀ are preferably ≤20 μm, more preferably ≤15 μm and most preferably ≤12 μm.

The volume-weighted particle size distribution of the silicon-containing material has a span d₉₀-d₁₀ of preferably ≤15.0 μm, more preferably ≤12.0 μm, more preferably ≤10.0 μm, especially preferably ≤8.0 μm, and most preferably ≤4.0 μm. The volume-weighted particle size distribution of the silicon-containing material has a span d₉₀-d₁₀ of preferably ≥0.6 μm, more preferably ≥0.8 μm and most preferably ≥1.0 μm.

The silicon-containing material is preferably in the form of particles. The particles may be isolated or agglomerated. The silicon-containing material is preferably not aggregated and preferably not agglomerated. The terms isolated, agglomerated and unaggregated have already been defined earlier on above in relation to the porous particles. The presence of silicon-containing materials in the form of aggregates or agglomerates may be made visible, for example, by means of conventional scanning electron microscopy (SEM).

The silicon-containing material may have any desired morphology, and may therefore, for example, be sputtery, platy, spherical or else acicular, with sputtery or spherical particles being preferred.

According to the Wadell's definition, the sphericity y is the ratio of the surface area of a sphere of equal volume to the actual surface area of a body. In the case of a sphere, the value of V is 1. According to this definition, the silicon-containing materials have a sphericity ψ of preferably 0.3 to 1.0, more preferably of 0.5 to 1.0, and most preferably of 0.65 to 1.0.

Sphericity S is the ratio of the circumference of an equivalent circle with the same area A as the projection of the particle projected onto a surface, to the measured circumference U of this projection: S=2\sqrt{πA}/U. In the case of a particle of ideal circularity, the value of S would be 1. For the silicon-containing materials, the sphericity S is in the range from preferably 0.5 to 1.0 and more preferably from 0.65 to 1.0, based on the percentiles S₁₀ to S₉₀ of the numerical sphericity distribution. The sphericity ψ is measured, for example, from optical micrographs of individual particles or preferably, in the case of particles <10 μm, with a scanning electron microscope, by graphic evaluation by means of image analysis software, such as ImageJ, for example.

The cycling stability of lithium ion batteries can be increased further via the morphology, the material composition, in particular the specific surface area or the internal porosity of the silicon-containing material.

The silicon-containing material contains preferably 10 to 90 wt %, more preferably 20 to 80 wt %, very preferably 30 to 60 wt % and especially preferably 40 to 50 wt % of porous particles, based on the total weight of the silicon-containing material.

The silicon-containing material contains preferably 10 to 90 wt %, more preferably 20 to 80 wt %, very preferably 30 to 60 wt % and especially preferably 40 to 50 wt % of silicon obtained via deposition from the silicon precursor, based on the total weight of the silicon-containing material (determined preferably by elemental analysis, such as ICP-OES).

If the porous particles comprise silicon compounds, in the form of silicon dioxide, for example, the above-mentioned wt % figures for the silicon obtained via deposition from the silicon precursor can be determined by subtracting the silicon mass in the porous particles, ascertained by elemental analysis, from the silicon mass in the silicon-containing material, ascertained by elemental analysis, and dividing the result by the mass of the silicon-containing material.

The volume of the silicon contained in the silicon-containing material and obtained via deposition from the silicon precursor is a product of the mass fraction of the silicon obtained via deposition from the silicon precursor, as a proportion of the total mass of the silicon-containing material, divided by the density of silicon (2.336 g/cm³).

The pore volume P of the silicon-containing materials is a product of the sum of gas-accessible and gas-inaccessible pore volume. The Gurwitsch gas-accessible pore volume of the silicon-containing material can be determined by gas sorption measurements with nitrogen in accordance with DIN 66134.

The gas-inaccessible pore volume of the silicon-containing material can be determined by the equation:

Gas-inaccessible pore volume=1/pure-material density−1/skeletal density.

Here, the pure-material density of a silicon-containing material is a theoretical density which can be calculated from the sum of the theoretical pure-material densities of the components contained in the silicon-containing material, multiplied by their respective weight-based percentage fraction in the overall material. Accordingly, for example, for a silicon-containing material wherein silicon is deposited on a porous particle:

Pure-material density=theoretical pure-material density of the silicon*fraction of the silicon in wt %+theoretical pure-material density of the porous particles*fraction of the porous particles in wt^{%}.

Data on pure-material densities can be taken by the skilled person from, for example, the Ceramic Data Portal of the National Institute of Standards (NIST, https://srdata.nist.gov/CeramicDataPortal/scd). For example, the pure-material density of silicon oxide is 2.203 g/cm³, that of boron nitride is 2.25 g cm³, that of silicon nitride is 3.44 g/cm³, and that of silicon carbide is 3.21 g/cm³.

The pore volume P of the silicon-containing materials is situated in the range from 0 to 400 vol %, preferably in the range of 100 to 350 vol % and more preferably in the range from 200 to 350 vol %, based on the volume of the silicon contained in the silicon-containing material and obtained from the deposition of the silicon precursor.

The porosity contained in the silicon-containing material may be both gas-accessible and gas-inaccessible. The ratio of the volume of gas-accessible to gas-inaccessible porosity of the silicon-containing material may be situated generally in the range from 0 (no gas-accessible pores) to 1 (all pores are gas-accessible). The ratio of the volume of gas-accessible to gas-inaccessible porosity of the silicon-containing material is situated preferably in the range from 0 to 0.8, more preferably in the range from 0 to 0.3, and especially preferably from 0 to 0.1.

The pores of the silicon-containing material may have any desired diameters, being situated, for example, in the range of macropores (>50 nm), mesopores (2-50 nm) and micropores (<2 nm). The silicon-containing material may also contain any desired mixtures of different pore types. The silicon-containing material preferably contains at most 30% of macropores, based on the total pore volume, particular preference being given to a silicon-containing material without macropores, and very particular preference to a silicon-containing material having at least 50% of pores, based on the total pore volume, having a mean pore diameter of below 5 nm. With more particular preference the silicon-containing material exclusively has pores with a diameter of at most 2 nm.

The silicon-containing material comprises silicon structures which in at least one dimension have structure sizes of preferably at most 1000 nm, more preferably less than 100 nm, very preferably less than 5 nm (method of determination: scanning electron microscopy (SEM) and/or high-resolution transmission electron microscopy (HR-TEM)).

The silicon-containing material preferably comprises silicon layers having a layer thickness of below 1000 nm, more preferably less than 100 nm, very preferably less than 5 nm (method of determination: scanning electron microscopy (SEM) and/or high-resolution transmission electron microscopy (HR-TEM)). The silicon-containing material may also comprise silicon in the form of particles. The silicon particles have a diameter of preferably at most 1000 nm, more preferably less than 100 nm, very preferably less than 5 nm (method of determination: scanning electron microscopy (SEM) and/or high-resolution transmission electron microscopy (HR-TEM)). The figure for the silicon particles here is based preferably on the diameter of the circle around the particles in the microscope image.

The silicon-containing material has a specific surface area of preferably at most 50 m²/g, more preferably less than 30 m²/g, and especially preferably less than 10 m²/g. The BET surface area is determined according to DIN 66131 (with nitrogen). Accordingly, when the silicon-containing material is used as active material in anodes for lithium ion batteries, SEI formation can be reduced and the initial coulombic efficiency can be enhanced.

The silicon in the silicon-containing material, deposited from the silicon precursor, may further comprise dopants, selected for example from the group containing Li, Fe, Al, Cu, Ca, K, Na, S, Cl, Zr, Ti, Pt, Ni, Cr, Sn, Mg, Ag, Co, Zn, B, P, Sb, Pb, Ge, Bi, rare earths, or combinations thereof. Preference here is given to lithium and/or tin. The amount of dopants in the silicon-containing material is preferably at most 1 wt % and more preferably at most 100 ppm, based on the total weight of the silicon-containing material, determinable by means of ICP-OES.

The silicon-containing material generally has a surprisingly high stability under compressive and/or shearing load. The pressure stability and shear stability of the silicon-containing material are manifested, for example, by the absence or virtual absence of changes in the porous structure of the silicon-containing material in the SEM under compressive load (for example on electrode compaction) and, respectively, shearing load (for example, on preparation of the electrodes).

The silicon-containing material may optionally further comprise additional elements, such as carbon for example. Carbon is present preferably in the form of thin layers having a layer thickness of at most 1 μm, preferably less than 100 nm, more preferably less than 5 nm, and very preferably less than 1 nm (determinable via SEM or HR-TEM). These carbon layers may be on the inner surface of pores and/or on the outer surface of the silicon-containing material. The sequence of different layers in the silicon-containing material through the use of different reactive gases in multiple phases 3 and the number of these layers are also arbitrary. Accordingly, there may first be a layer, on the porous particles, of a further material, different from the porous particles, such as carbon, for example, and that layer may bear a silicon layer or a layer of silicon particles. Also possible is the presence, on the silicon layer or on the layer of silicon particles, of a layer, in turn, of a further material, which may be different from or the same as the material of the porous particles, irrespective of whether, between the porous particles and silicon layer or the layer consisting of silicon particles, there is a further layer of a material different from the material of the porous particles. The process of the invention proves here to be particularly advantageous, since multiple coatings are possible without interruption by opening the fluidized bed reactor.

The silicon-containing material contains preferably ≤50 wt %, more preferably ≤40 wt % and especially preferably ≤20 wt % of additional elements. The silicon-containing material contains preferably ≥1 wt %, more preferably ≥3 wt % and especially preferably ≥2 wt % of additional elements. The figures in wt % are based on the total weight of the silicon-containing material. In an alternative embodiment, the silicon-containing material contains no additional elements.

The present invention further provides for the use of the silicon-containing material produced by the process of the invention as an active material in anode materials for anodes of lithium ion batteries, and also for the use of the anodes of the invention for production of lithium ion batteries.

The anode material is based preferably on a mixture comprising the silicon-containing material accessible by the process of the invention, one or more binders, optionally graphite as further active material, optionally one or more further electrically conducting components, and optionally one or more additives.

Through the use of further electrically conducting components in the anode material it is possible to reduce the contact resistances within the electrode and also between electrode and current collector, thereby improving the current-carrying capacity of the lithium ion battery. Examples of preferred further electrically conducting components are conductive carbon black, carbon nanotubes or metallic particles, such as copper, for example.

The primary particles of conductive carbon black preferably have a volume-weighted particle size distribution between the diameter percentiles d₁₀=5 nm and d₉₀=200 nm. The primary particles of conductive carbon black may also have chainlike branching and form structures of up to μm size. Carbon nanotubes preferably have diameters of 0.4 to 200 nm, more preferably 2 to 100 nm and most preferably 5 to 30 nm. The metallic particles have a volume-weighted particle size distribution which lies preferably between the diameter percentiles d₁₀=5 nm and d₉₀=800 nm.

The anode material comprises preferably 0 to 95 wt %, more preferably 0 to 40 wt % and most preferably 0 to 25 wt % of one or more further electrically conducting components, based on the total weight of the anode material.

In the anodes for lithium ion batteries, the silicon-containing material may be present at preferably 5 to 100 wt %, more preferably 30 to 100 wt % and most preferably 60 to 100 wt %, based on the total active material present in the anode material.

Preferred binders are polyacrylic acid or the alkali metal salts thereof, more particularly lithium salts or sodium salts, polyvinyl alcohols, cellulose or cellulose derivatives, polyvinylidene fluoride, polytetrafluoroethylene, polyolefins, polyimides, especially polyamideimides, or thermoplastic elastomers, especially ethylene-propylene-diene terpolymers. Particularly preferred are polyacrylic acid, polymethacrylic acid or cellulose derivatives, especially carboxymethylcellulose. Particular preferred also are the alkali metal salts, especially lithium salts or sodium salts, of the aforesaid binders. The most preferred are the alkali metal salts, especially lithium salts or sodium salts, of polyacrylic acid or of polymethacrylic acid. All or preferably a proportion of the acid groups of a binder may be present in the form of salts. The binders have a molar mass of preferably 100 000 to 1 000 000 g/mol. Mixtures of two or more binders may also be used.

As graphite it is possible generally to use natural or synthetic graphite. The graphite particles preferably have a volume-weighted particle size distribution between the diameter percentiles d₁₀>0.2 μm and d₉₀≤200 μm.

Examples of additives are pore formers, dispersants, flow control agents or dopants, an example being elemental lithium.

Preferred formulations for the anode material comprise preferably 5 to 95 wt %, more particularly 60 to 90 wt %, of the silicon-containing material, 0 to 90 wt %, more particularly 0 to 40 wt %, of further electrically conducting components 0 to 90 wt %, more particularly 5 to 40 wt %, of graphite, 0 to 25 wt %, more particularly 5 to 20 wt %, of binders and 0 to 80 wt %, more particularly 0.1 to 5 wt %, of additives, with the figures in wt % being based on the total weight of the anode material and with the fractions of all the constituents of the anode material adding up to a sum of 100 wt %.

The constituents of the anode material making up an anode ink or anode paste can be processed, for example, in a solvent, preferably selected from the group encompassing water, hexane, toluene, tetrahydrofuran, N-methylpyrrolidone, N-ethylpyrrolidone, acetone, ethyl acetate, dimethyl sulfoxide, dimethylacetamide and ethanol, and also mixtures of these solvents, preferably using rotor-stator machines, high-energy mills, planetary kneaders, stirred ballmills, shaking plates or ultrasonic apparatuses.

The anode ink or anode paste has a pH of preferably 2 to 7.5 (determined at 20° C., using, for example, the WTW pH 340i pH meter with SenTix RJD probe).

The anode ink or anode paste can be applied by doctor blade, for example, to a copper foil or another current collector. Other coating methods, such as rotational coating (spin coating), roller coating, dipping or slot-die coating, painting or spraying, for example, may also be used in accordance with the invention.

Before being coated with the anode material of the invention, the copper foil is preferably treated with a commercial primer, based for example on polymer resins or silanes. Primers can lead to an improvement in the adhesion to the copper, but themselves generally possess virtually no electrochemical activity.

The anode material is generally dried to constant weight. The drying temperature is guided by the components used and by the solvent employed. It is situated preferably between 20 and 300° C., more preferably between 50 and 150° C.

The layer thickness, meaning the dry layer thickness of the anode coating, is preferably 2 to 500 μm, more preferably from 10 to 300 μm.

Lastly, the electrode coatings are preferably be calendered, in order to set a defined porosity. The electrodes thus produced preferably have porosities of 15 to 85%, which can be determined via mercury porosimetry in accordance with DIN ISO 15901-1. Here, preferably to 85% of the pore volume which can be determined in this way is provided by pores which have a pore diameter of 0.01 to 2 μm.

The invention further provides lithium ion batteries comprising a cathode, an anode, two electrically conducting connections to the electrodes, a separator, and an electrolyte, with which the separator and the two electrodes are impregnated, and also a casing accommodating the stated components, characterized in that the anode comprises silicon-containing material obtained by the process of the invention.

In the context of this invention, the term lithium ion battery also encompasses cells. Cells generally comprise a cathode, an anode, a separator and an electrolyte. Besides one or more cells, lithium ion batteries preferably further comprise a battery management system. Battery management systems serve generally to control batteries, by means of electronic circuits, for example, especially for recognizing the charge state, for protection from exhaustive discharge, or for protection against overcharging.

Preferred cathode materials which can be used in the invention include lithium cobalt oxide, lithium nickel oxide, lithium nickel cobalt oxide (doped or undoped), lithium manganese oxide (spinel), lithium nickel cobalt manganese oxides, lithium nickel manganese oxides, lithium iron phosphate, lithium cobalt phosphate, lithium manganese phosphate, lithium vanadium phosphate, or lithium vanadium oxides.

The separator is generally an electrically insulating, ion-permeable membrane, preferably made of polyolefins, for example polyethylene (PE) or polypropylene (PP), or polyester, or corresponding laminates. Alternatively, as is customary within battery manufacture, the separator may consist of or be coated with glass or ceramic materials. The separator, conventionally, separates the first electrode from the second electrode and therefore prevents electrically conducting connections between the electrodes (short circuiting).

The electrolyte is preferably a solution comprising one or more lithium salts (=conductive salt) in an aprotic solvent. Conductive salts are preferably selected from the group containing lithium hexafluorophosphate, lithium hexafluoroarsenate, lithium perchlorate, lithium tetrafluoroborate, lithium imides, lithium methides, lithium trifluoromethanesulfonate LiCF₃SO₃, lithium bis(trifluoromethanesulfonimide) and lithium borates. The concentration of the conductive salt, based on the solvent, is preferably between 0.5 mol/l and the solubility limit of the salt in question. More preferably it is 0.8 to 1.2 mol/l.

Solvents used in accordance with the invention may preferably be cyclic carbonates, propylene carbonate, ethylene carbonate, fluoroethylene carbonate, dimethyl carbonate, diethyl carbonate, ethyl methyl carbonate, dimethoxyethane, diethoxyethane, tetrahydrofuran, 2-methyltetrahydrofuran, gamma-butyrolactone, dioxolane, acetonitrile, organic esters of carbonic acid, or nitriles, individually or as mixtures thereof.

The electrolyte preferably comprises a film former, such as vinylene carbonate or fluoroethylene carbonate, for example. In this way it is possible to achieve a significant improvement in the cycling stability of the anodes comprising the silicon-containing active material obtained by the process of the invention. This improvement is ascribed primarily to the formation of a solid electrolyte interphase on the surface of active particles. The fraction of the film former in the electrolyte is preferably between 0.1 and 20.0 wt %, more preferably between 0.2 and 15.0 wt % and most preferably between 0.5 and 10 wt %.

In order to match the actual capacities of the electrodes of a lithium-ion cell to one another in an as optimal a way as possible, it is advantageous to balance out, in terms of quantity, the materials for the positive and negative electrodes. Of particular importance in this context is the fact that, in the first or initial charging/discharging cycle of secondary lithium-ion cells (known as activation), a covering layer is formed on the surface of the electrochemically active materials in the anode. This covering layer is referred to as a solid electrolyte interphase (SEI) and consists in general mainly of electrolyte decomposition products and also a certain amount of lithium, which is accordingly no longer available for further charging/discharging reactions.

The thickness and composition of the SEI are dependent on the nature and the quality of the anode material used and of the electrolyte solution used. In the case of graphite, the SEI is particularly thin. On graphite there is a loss of typically 5 to 35% of the mobile lithium in the first charging step. There is also, correspondingly, a drop in the reversible capacity of the battery.

In the case of anodes with the silicon-containing material obtained by the process of the invention, the first charging step is accompanied by a loss of mobile lithium of preferably at most 30%, more preferably at most 20% and most preferably at most 10%, which is well below the values described in the prior art, such as in U.S. Pat. No. 10,147,950 B1, for example.

The lithium ion battery of the invention can be produced in all customary forms, such as in rolled, folded or stacked form, for example.

All substances and materials utilized for production of the lithium ion batteries of the invention as described above are known. The parts of the battery the invention are produced, and they are assembled to give the battery the invention, by the processes known within the field of battery manufacture.

The silicon-containing material obtained by the process of the invention is notable for significantly improved electrochemical characteristics, and leads to lithium ion batteries having high volumetric capacities and outstanding performance properties. The silicon-containing material obtained by the process of the invention is permeable to lithium ions and also electrons, and therefore allows charged transport. The SEI in lithium ion batteries can be reduced to a large extent with the silicon-containing material obtained by the process of the invention. In addition, because of the design of the silicon-containing material obtained with the process of the invention, there is no longer any detachment, or at least greatly reduced detachment, of the SEI from the surface of the active material. All of this results in a high cycling stability on the part of such lithium ion batteries whose anodes contain the silicon-containing material obtainable by the process of the invention.

The examples which follow serve for further elucidation of the invention described here.

Analytical methods and instruments used for the characterization were as follows:

### Scanning Electron Microscopy (SEM/EDX):

The microscopic analyses were carried out with a Zeiss Ultra 55 scanning electron microscope and an Oxford X-Max 80N energy-dispersive x-ray spectrometer. Prior to the analysis, the samples were subjected to vapor deposition of carbon with a Safematic Compact Coating Unit 010/HV in order to prevent charging phenomenon. The cross sections of the silicon-containing materials that are shown in the figures were produced using a Leica TIC 3× ion cutter at 6 kV.

### Inorganic Analysis/Elemental Analysis:

The C contents reported in the examples were ascertained using a Leco CS 230 analyzer; for determination of 0 and, where appropriate N and H contents, a Leco TCH-600 analyzer was used. The qualitative and quantitative determination of other reported elements in the silicon-containing materials obtained took place by means of ICP (inductively coupled plasma) emission spectrometry (Optima 7300 DV, from Perkin Elmer). For this analysis, the samples were subjected to acid digestion (HF/HNO₃) in a microwave (Microwave 3000, from Anton Paar). The ICP-OES determination is guided by ISO 11885 “Water quality—Determination of selected elements by inductively coupled plasma optical emission spectrometry (ICP-OES) (ISO 11885:2007); German version EN ISO 11885:2009”, which is used for analysis of acidic, aqueous solutions (e.g., acidified samples of drinking water, wastewater and other water, aqua regia extracts of soils and sediments).

### Particle Size Determination:

The particle size distribution was determined in the context of this invention according to ISO 13320 by means of static laser scattering using a Horiba LA 950. In the preparation of the samples, particular attention must be paid here to the dispersing of the particles in the measurement solution, so as not to measure the size of agglomerates rather than individual particles. For the porous starting materials and silicon-containing materials being examined here, the particles were dispersed in ethanol. For this purpose the dispersion, prior to the measurement, was treated as and when required with 250 W ultrasound in a Hielscher model UIS250v ultrasound laboratory instrument with LS24d₅ sonotrode for 4 minutes.

### BET Surface Area Measurement:

The specific surface area of the materials was measured via gas adsorption with nitrogen, using a Sorptomatic 199090 instrument (Porotec) or an SA-9603MP instrument (Horiba) by the BET method (determination according to DIN ISO 9277:2003-05 with nitrogen).

### Skeletal Density:

The skeletal density, i.e., density of the porous solid based on the volume exclusively of the pore spaces gas-accessible from the outside, was determined by means of He pycnometry in accordance with DIN 66137-2.

### Gas-Accessible Pore Volume:

The Gurwitsch gas-accessible pore volume was determined by gas sorption measurements with nitrogen in accordance with DIN 66134.

### Determination of Fluidization Index:

The fluidization index is the ratio of measured pressure drop and the theoretically maximum possible pressure drop. For the determination of the fluidization index, it is necessary to measure the pressure drop of the fluidized bed. The pressure drop is measured as the pressure differential measurement between the upper and lower ends of the fluidized bed. The pressure differential measuring instrument converts the pressures detected at membranes to digital values and displays the pressure differential. The pressure measurement conduits should be designed such that they are disposed immediately above the gas-permeable base and immediately above the fluidized bed. For the determination of the fluidization index, in addition, the exact determination of the weight of the particle bed introduced is necessary. See also [VDI-Wärmeatlas 11th edition, section L3.2 Strömungsformen and Druckverlust in Wirbelschichten, p. 1371-1382, Springer Verlag, Berlin Heidelberg, 2013].

### Determination of Minimum Fluidization Velocity:

Minimum fluidization velocity is the fluidization velocity based on the superficial cross-sectional reactor area at which the particle bed changes from a fixed bed through which gas flows to a fluidized bed. By simultaneous measurement of the fluidizing gas flow rate by means of a regulated mass flow meter and of the pressure drop by a digital means of measuring the pressure differential across the fluidized bed, it is possible to ascertain the minimum fluidization velocity. With knowledge of the cross-sectional area of the reactor, it is possible to use the measured fluidizing gas flow rate to calculate the fluidizing gas velocity. The progression of the pressure drop recorded against the fluidizing gas velocity is referred to as the fluidized bed characteristic. It should be noted that the fluidized bed characteristic is recorded proceeding from a high fluidizing gas velocity by stepwise reduction in that velocity. In the case of pure fixed bed flow, the pressure drop increases in a linear manner. The corresponding fluidization index FI is less than one. In the case of a fully formed fluidized bed, the measured pressure drop is constant. The corresponding fluidization index FI is equal to one. At the transition between the two regions is the state of minimal fluidization. The corresponding fluidizing gas velocity based on the superficial cross-sectional reactor area is equal to the minimum fluidization velocity. If the transition from the fixed bed to the fluidized bed is characterized by a region, the point of intersection of the extrapolated fixed bed characteristic and the extrapolated fluidized bed characteristic is defined as the point of minimal fluidization. See also [VDI-Wärmeatlas 11th edition, section L3.2 Strömungsformen and Druckverlust in Wirbelschichten, p. 1371-1382, Springer Verlag, Berlin Heidelberg, 2013].

### Measurement of Heat Transfer:

In order to determine the heat transfer between any surface and the fluidized bed, a heat flow probe is used. The probe is set up such that a defined heat flow \dot{Q} is generated in the probe by resistance heating, which is released to the fluidized bed over a defined is determined. The coefficient of heat transfer can be calculated by the following equation:

$$α = \frac{\dot{Q}}{A \cdot ( {T}_{A} - {T}_{W S} )}$$

### Determination of Agglomerate Size:

In order to determine the size of the agglomerates formed in the fluidization of the porous particles and of the silicon-containing materials of Geldart class C, samples are taken from the fluidized bed reactor. The sampling is effected by stopping the fluidizing gas and opening the reactor. It should be ensured that the sampling does not change the size of the agglomerates. In order to determine the agglomerate size, the agglomerates are examined by means of high-resolution optical digital microscopy. The result reported may be a size range for the agglomerates.

The fluidized bed reactor used for the performance of the experimental examples consisted of a cylindrical portion having an external diameter of 160 mm and having a height of 1200 mm. The cylindrical Portion was composed of a based chamber and the actual fluidized bed reactor. The two parts were separated from one another by the gas-permeable base. Above the cylindrical reactor portion, there was a connected reactor portion with a widening cross section to twice the cross-sectional area compared to the cylindrical reactor portion. At the upper end of the reactor was a lid with filter elements for the exit of gas and connections for the introduction of temperature sensors and a heat flow probe. The reaction temperature was adjusted via the heating of the reactor wall, and the height of the heated region was 80% of the cylindrical length beginning at the gas-permeable base. The heating was electrical. The fluidizing gas was preheated with a gas heater in accordance with the process phase preceding the introduction into the fluidized bed reactor. The pulsation of the fluidizing gas stream was achieved by the use of a directly controlled magnetic valve. The heat flow probe was installed 7 cm above the gas-permeable base. The reaction temperature was ascertained by multiple temperature sensors in the fluidized bed that were distributed axially at a constant distance from the reactor wall.

In preliminary experiments, by measurements of pressure drop across the fluidized bed and by heat transfer analyses with the aid of the heat flow probe for different gas compositions and temperatures, the minimum fluidization velocities and maximum coefficient of heat transfer were ascertained for the porous particles used in the examples that follow and the fluidizing gases used.

### Example 1

Production of a Silicon-Containing Material in a Fluidized Bed Reactor with Pulsed Fluidizing Gas Stream:

In phase 1 of the process, 1000 g of an amorphous carbon in the form of porous particles (spec. surface area=1907 m²/g, pore volume=0.96 cm³/g, median volume-weighted particle size D₅₀=2.95 μm, particle density=0.7 g/cm³, Geldart class C particles) was introduced into the reactor.

In phase 2, the particle bed was fluidized with a fluidizing gas consisting of nitrogen, fixing the amount of gas such that the minimum fluidization velocity was at least 3 times that ascertained in the preliminary experiments. At the same time, with the aid of the magnetic valve, the gas stream was induced to oscillate, with a frequency between the open and closed positions of the valve of 3 Hz. The measurement of pressure drop and the measurement of heat transfer gave a fluidization index of FI=0.99 and a coefficient of heat transfer, based on the maximum coefficient of heat transfer determined with optimal fluidization at the same temperature and with the same gas composition of a/aₘₐₓ=0.98. Once a stable fluidized bed had formed, the fluidizing gas was stopped and the reactor was opened in order to take samples for the determination of agglomerate size at different points in the bed of particles in the fluidized bed reactor. The size of the agglomerates was 237+/−50 μm. Subsequently, the reactor was closed again, and the fluidization was restarted. Once a stable fluidized bed had formed again (FI=0.99 and a/aₘₐₓ=0.99), the temperature in the reactor was increased to a temperature between 400 and 450° C. During the increase in temperature, the fluidization index FI was 0.99 and the relative coefficient of heat transfer a/aₘₐₓ was 0.98. On account of the increase in temperature, the fluidizing gas flow rate had to be adjusted for this purpose.

On attainment of the reaction temperature of 400 to 450° C., in phase 3 of the process, the fluidizing gas consisting of pure nitrogen was replaced by a fluidizing gas consisting of 5 vol % of monosilane SiH₄ as silicon precursor in nitrogen. The pulsation of the gas stream with the frequency between the open and closed positions of the valve of 3 Hz remained constant during and after the exchange of the fluidizing gases, and values for the fluidization index of FI=0.98 and the relative coefficient of heat transfer of α/αₘₐₓ=0.98 were still ascertained. Because of the change in density of the porous particles during the deposition of silicon, the gas rate of the fluidizing gas was adjusted such that the values of the fluidizing index and of the relative coefficient of heat transfer were always greater than 0.95.

After a reaction time of 220 minutes, in phase 4, the fluidizing gas was switched back to a pulsed nitrogen stream, again obtaining values for the fluidization index FI=0.99 and the relative coefficient of heat transfer of α/αₘₐₓ=0.99. The heating output was reduced. On attainment of a temperature of 50° C., the fluidizing gas stream was switched to a fluidizing gas consisting of 5 vol % of oxygen in nitrogen and was maintained for 60 min in order to allow control reaction of any reactive groups present on the surface of the product obtained. Subsequently, the reactor was cooled to room temperature.

After the reactor had been opened, in phase 5, samples were taken from the bed at different points. The size of the agglomerates was determined using these samples. It was possible here to ascertain average agglomerate sizes of 289+/−70 μm.

After the sampling, 2248 g of a black solid-state material was discharged from the reactor. The silicon-containing material obtained was introduced into a cylindrical vessel and homogenized in a drum hoop mixer. The agglomerates formed by the fluidized bed process could be eliminated by sieving without difficulty. Samples for physicochemical analysis, for electrochemical analysis and for electron microscopy studies were taken from the homogenized and sieved product.

The analytical data of the solid-state material obtained are listed in table 1.

For the electron microscopy studies, the product particles were individualized and embedded into epoxy resin. In order to assess the silicon distribution within the particles, the particles embedded in epoxy resin were cut.

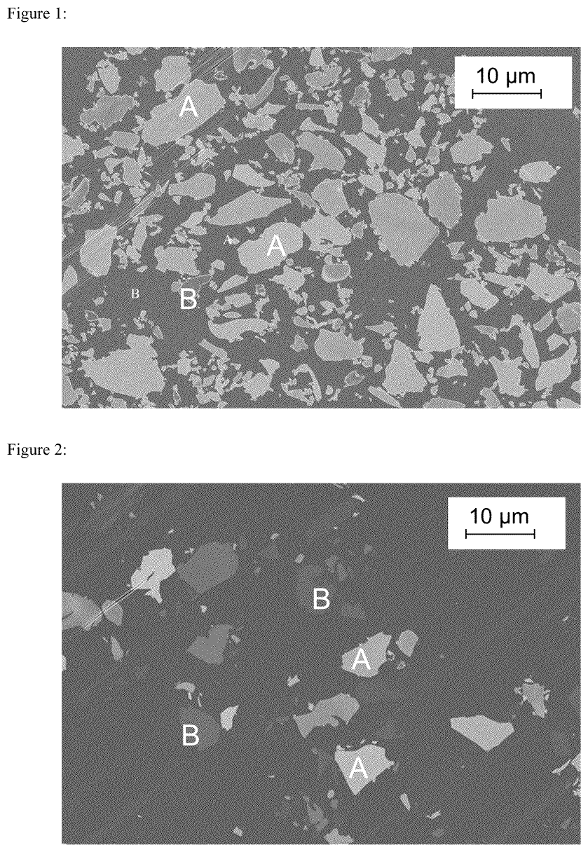

FIG. 1 shows the SEM section through the particles for a representative sample. It can be seen therein that silicon-infiltrated porous particles (A) appear in a lighter color than the porous particles themselves (B). It is apparent that the predominant majority of the product particles have a light-colored hue, and hence homogeneous, uniform deposition of silicon has taken place in the pores.

### Example 2

Production of a Silicon-Containing Material with a Carbon Coating in a Fluidized Bed Reactor with a Pulsed Fluidizing Gas Stream:

For the procedure, the same porous particles (spec. surface area=1907 m²/g, pore volume=0.96 cm³/g, median volume-weighted particle size D₅₀=2.95 μm, particle density=0.7 g/cm³, Geldart class C particles) as used in example 1 were used. The same amount of 1000 g was also introduced into the reactor.

The performance of phases 2 and 3 likewise ran analogously to example 1 with the same fluidizing gas streams and the same pulsation frequency. After the silicon deposition in phase 3 had ended, phase 4 was omitted and, in a second phase 2, the fluidizing gas was switched to a pure pulsed nitrogen stream. The reactor temperature was then set to a temperature of 700 to 750° C. The fluidizing gas stream had to be adjusted again because of the increase in temperature.

On attainment of the reaction temperature of 700 to 750° C., phase 3 of the process was conducted again, for which fluidizing gas consisting of pure nitrogen was replaced by a fluidizing gas consisting of 5% by volume of ethyne C₂H₂ as carbon precursor in nitrogen. The pulsation of the gas stream with a frequency between the open and closed positions of the valve of 3 Hz was maintained during and after the change of fluidizing gases, and values for the fluidization index of FI=0.99 and the relative coefficient of heat transfer of α/αₘₐₓ=0.98 were ascertained. As a result of the only insignificant increase in weight as a result of the carbon coating, there was no need to adjust the fluidizing gas stream.

After a reaction time of 80 minutes, phase 4 was conducted: the fluidizing gas was switched to a pulsed nitrogen stream; as a result of adjustment of the gas stream during the cooling, values for the fluidization index FI=0.98 and the relative coefficient of heat transfer of α/αₘₐₓ=0.97 were again obtained. The heating was switched off and the reactor was cooled down to room temperature.

After the reactor had been opened, in phase 5, samples were taken from the bed at different points in the reactor. These samples were used to determine the size of the agglomerates. Here, by comparison with example 1, coarser agglomerates with an average diameter of 358+/−90 μm were found.

After sampling, 2360 g of a black solid was discharged from the reactor. The silicon-containing material obtained was introduced into a cylindrical vessel and homogenized in a drum hoop mixer. The agglomerates formed by the fluidized bed process could be eliminated by sieving without difficulty. Samples were taken from the homogenized sieved product for the physicochemical analysis and for the electrochemical analysis. The analytical data of the solid obtained are listed in table 1.

### Comparative Example 3

Production of a Silicon-Containing Material in a Fluidized Bed Reactor without Pulsation of the Fluidizing Gas:

Comparative example 3 was performed analogously to example 1. The same porous particles (spec. surface area=1907 m²/g, pore volume=0.96 cm³/g, median volume-weighted particle size D₅₀=2.95 μm, particle density=0.7 g/cm³, Geldart class C particles) as used in examples 1 and 2 were used. The same amount of 1000 g was again introduced into the reactor in phase 1.

In phase 2, exactly the same fluidizing gas streams were established as an example 1, but without pulsation of the fluidizing gas stream. The determination of the homogeneity of the fluidized bed gives a fluidization index of FI=0.78 and a coefficient of heat transfer, based on the maximum coefficient of heat transfer determined with optimal fluidization with pulsation at the same temperature and gas composition, of α/αₘₐₓ=0.63. It was possible to infer from these values that the particle bed was not fully fluidized. It was also not possible to determine this from the agglomerate diameters ascertained here. In the upper region of the bed, it was possible to measure agglomerate diameters of 650+/−300 μm. In the lower region of the bed, agglomerates were removed via the gas-permeable base, which had a size of 3000+/−1000 μm. This wide range of agglomerates of different size in combination with the partial fluidization is typical of the formation of an ABF fluidized bed.

In phase 3 of the process, analogously to example 1, on attainment of the reaction temperature of 400 to 450° C., the fluidizing gas consisting of pure nitrogen was replaced by a fluidizing gas consisting of 5% by volume of monosilane SiH₄ as silicon precursor in nitrogen. For the fluidization index and the relative coefficient of heat transfer, values of FI=0.75 and a/aₘₐₓ=0.58 were ascertained. As in phase 2, the values suggested an inhomogeneously fluidized bed during the deposition process. Because of the change in density of the porous particles during the deposition of the silicon, the gas rate of the fluidizing gas was altered analogously to the gas volumes set in example 1.

Analogously to example 1, after a reaction time of 220 minutes in phase 4, the fluidizing gas was switched back to a nitrogen stream. For the fluidization index and the relative coefficient of heat transfer, values of FI=0.76 and α/αₘₐₓ=0.62 were ascertained. The heating output was reduced. On attainment of a temperature of 50° C., the fluidizing gas stream was switched to a fluidizing gas consisting of 5% by volume of oxygen in nitrogen and maintained for 60 min in order to allow control reaction of any reactive groups present on the surface of the product obtained. Subsequently, the reactor was cooled to room temperature.

After the reactor had been opened, in phase 5, samples were taken from the bed at different points in the reactor. Here, in the upper region of the bed, agglomerates of size 700+/−300 μm were measured. Directly above the gas-permeable base, agglomerates of size 3500+/−1000 μm had formed.

After the sampling, 2150 g of a black solid was discharged from the reactor. The silicon-containing material obtained was introduced into a cylindrical vessel and homogenized in a drum hoop mixer. The agglomerates formed by the fluidized bed process could be eliminated by sieving without difficulty. Samples of the homogenized, sieved product were taken for physicochemical analysis, for electrochemical analysis and for electron microscopy studies. The analytical data of the solid obtained are listed in table 1.

For the electron microscopy studies, product particles were individualized and embedded in epoxy resin. In order to assess the silicon distribution within the particles, the particles embedded in epoxy resin were cut. FIG. 2 shows the SEM section through the particles for a representative sample. It can be seen therein that silicon-infiltrated porous particles (A) have a lighter appearance than the porous particles themselves (B). It is apparent that there is great inhomogeneity in the silicon distribution, even though the process conditions were the same apart from the pulsation. It can be concluded from this that only by the process of the invention as described in claim 1 can homogeneous products be produced.

With an increase in the fluidizing gas flow compared to example 1 for a possible increase in the homogeneity of the fluidized bed even without pulsation, it was not possible to achieve comparative values for the relative coefficient of heat transfer to those in inventive example 1. In addition, with a higher fluidizing gas flow, elevated particle discharge is to be expected. Another disadvantage would be a drop in the contact time between solid-state surface and gas with elevated fluidizing gas flow, which leads to a lower conversion of the reactive constituents used in the fluidizing gas stream.

TABLE 1
Analytical data:

| Example | Silicon content | BET surface | Oxygen content |
|---|---|---|---|
| number | wt %(ICP) | area m²/g | wt % (EA) |
| Ex. 1 | 56 | 11 | 3.8 |
| Ex. 2 | 53 | 5 | 2.5 |
| CEx. 3 | 54 | 42 | 8.9 |
| CEx. 4 | 57 | 35 | 7.5 |

### Comparative Example 4

### Production of a Silicon-Containing Material in a Tubular Reactor:

A tubular reactor was charged with 3.0 g of the same porous carbon as in examples 1 to 3 (spec. surface area=1907 m²/g, pore volume=0.96 cm³/g, median volume-weighted particle size D₅₀=2.95 μm, particle density=0.7 g/cm³, Geldart class C particles) in a quartz glass boat. After inertization with nitrogen, the reactor was heated to 410° C. On attainment of the reaction temperature, a reactive gas (10% SiH₄ in N₂, 10 1 (STP)/h) was passed through the reactor for 5.2 h. The reactor was then purged with inert gas, before the product was subjected to heat treatment at 500° C. for 1 h. Before being removed from the reactor, the product was cooled down to room temperature under inert gas. The analytical data of the solid obtained are listed in table 1.

### Example 5

### Anode Containing a Silicon-Containing Material and Electrochemical Testing in a Lithium Ion Battery of the Invention:

29.71 g of polyacrylic acid (dried to constant weight at 85° C.; Sigma-Aldrich, Mw ˜450 000 g/mol) and 756.60 g of deionized water were agitated by means of a shaker (290 l/min) for 2.5 h until dissolution of the polyacrylic acid was complete. Lithium hydroxide monohydrate (Sigma-Aldrich) was added to the solution in portions until the pH was 7.0 (measured using WTW pH 340i pH meter with SenTix RJD probe). The solution was subsequently commixed by means of a shaker for a further 4 h. 3.87 g of the neutralized polyacrylic acid solution and 0.96 g of graphite (Imerys, KS6L C) was introduced into a 50 ml vessel and combined in a planetary mixer (SpeedMixer, DAC 150 SP) at 2000 rpm. Next, 3.35 g of the silicon-containing material from example 1 was stirred in at 2000 rpm for 1 minute. Then 1.21 g of an 8 percent dispersion of conductive carbon black and 0.8 g of deionized water were added and were incorporated at 2000 rpm on the planetary mixer. Dispersing then took place in the dissolver for 30 min at 3000 rpm and at a constant 20° C. The ink was degassed again in the planetary mixer at 2500 rpm for 5 minutes under reduced pressure.

The finished dispersion was then applied by means of a film applicator frame having a 0.1 mm gap height (Erichsen, model 360) to a copper foil having a thickness of 0.03 mm (Schlenk Metallfolien, SE-Cu58). The anode coating thus produced was subsequently dried for 60 minutes at 50° C. under an air pressure of 1 bar. The mean basis weight of the dry anode coating was 3.0 mg/cm² and the coating density was 0.7 g/cm³.

The electrochemical studies were carried out on a button cell (CR2032 type, Hohsen Corp.) in a 2-electrode arrangement. The electrode coating was used as counter-electrode or negative electrode (Dm=15 mm). A coating based on lithium nickel manganese cobalt oxide 6:2:2 with a content of 94.0% and a mean basis weight of 15.9 mg/cm² (obtained from the company SEI) was used as the working electrode or positive electrode (Dm=15 mm). A glass fiber filter paper (Whatman, GD Type D) impregnated with 60 μl electrolyte served as a separator (Dm=16 mm). The electrolyte used consisted of a 1.0 molar solution of lithium hexafluorophosphate in a 1:4 (v/v) mixture of fluoroethylene carbonate and diethyl carbonate.

The cell was constructed in a glovebox (<1 ppm H₂O, O₂); the water content in the dry mass of all the components used was below 20 ppm.

Electrochemical testing was carried out at 20° C. The cell was charged by the cc/cv (constant current/constant voltage) method with a constant current of 5 mA/g (corresponding to C/25) in the first cycle and of 60 mA/g (corresponding to C/2) in the subsequent cycles, and, after the voltage limit of 4.2 V had been reached, charging took place with constant voltage until the current fell below 1.2 mA/g (corresponding to C/100) or 15 mA/g (corresponding to C/8). The cell was discharged by the cc (constant current) method with a constant current of 5 mA/g (corresponding to C/25) in the first cycle and of 60 mA/g (corresponding to C/2) in the subsequent cycles, until the voltage limit of 2.5 V was reached. The specific current selected was based on the weight of the coating of the positive electrode. The electrodes were selected such as to establish a capacity ratio of cathode to anode of 1:1.2.

The following test results were obtained with the full lithium ion battery cell from example 5:
reversible specific capacity of the negative electrode in the second cycle:
1280 mAh/g (4.2-2.5 V)
number of cycles with ≥80% retention of capacity:
350 charging/discharging cycles.

### Example 6

Anode with Silicon-Containing Material from Example 2 and Electrochemical Testing in a Lithium Ion Battery of the Invention:

The silicon-containing material from example 2 obtained by the process of the invention was used to produce an anode as described in example 5. As described in example 5, the anode was built into a lithium ion battery and subjected to testing by the same procedure.

The following test results were obtained with the full lithium ion battery cell from example 6:
reversible specific capacity of the negative electrode in the second cycle:
1210 mAh/g (4.2−2.5 V)
number of cycles with ≥80% retention of capacity:
410 charging/discharging cycles.

### Comparative Example 7

Anode with Silicon-Containing Material from Comparative Example 3 and Electrochemical Testing in a Lithium Ion Battery:

The silicon-containing material from comparative example 3 that was not obtained by the method of the invention was used to produce an anode as described in example 5. As described in example 5, the anode was built into a lithium ion battery and subjected to testing by the same procedure.

The following test results were obtained with the full lithium ion battery cell from comparative example 7:
reversible specific capacity of the negative electrode in the second cycle:
1150 mAh/g (4.2−2.5 V)
number of cycles with ≥80% retention of capacity:
208 charging/discharging cycles.

### Comparative Example 8

Anode with Silicon-Containing Material from Comparative Example 4 and Electrochemical Testing in a Lithium Ion Battery:

The silicon-containing material from comparative example 4 that was not obtained by the method of the invention was used to produce an anode as described in example 5. As described in example 5, the anode was built into a lithium ion battery and subjected to testing by the same procedure.

The following test results were obtained with the full lithium ion battery cell from comparative example 8:
reversible specific capacity of the negative electrode in the second cycle:
1240 mAh/g (4.2−2.5 V)
number of cycles with ≥80% retention of capacity:
282 charging/discharging cycles.

TABLE 2
Results of electrochemical testing:

| | Reversible specific | Number of cycles | Coulombic |
|---|---|---|---|
| | capacity of the anode in | with ≥80% retention | efficiency of |
| | the second cycle [mAh/g] | of capacity | forming [%] |
| Ex. 5 | 1005 | 350 | 86.1 |
| Ex. 6 | 875 | 410 | 88.2 |
| CEx. 7 | 882 | 208 | 81.7 |
| CEx. 8 | 910 | 282 | 83.5 |

1-16. (canceled)

17. A process for producing silicon-containing materials, comprising:
reacting the silicon-containing materials in a fluidized bed reactor by deposition of silicon from at least one silicon precursor in pores and on the surface of porous particles of Geldart class C; and
providing a fluidizing gas stream in the fluidized bed reactor that is fully or partly induced to oscillate in a pulsed manner and propagates in the form of a wave and acts on the fluidized bed so as to form a homogeneously fluidized bed as a pulsed gas stream so as to form a homogeneously fluidized bed having a fluidization index FI of at least 0.95, wherein the pulsation has a frequency of 0.1 to 20 Hz and a pulse duty ratio of 0.1 to 0.9, and wherein the fluidizing gas stream has a superficial velocity which is above a measured minimum fluidization velocity of the pulsed gas stream, where the pulsation is combined with mechanical stirring as a further fluidizing aid.

18. The process of claim 17, wherein the process comprises at least the phases of:
Phase 1: filling the fluidized bed reactor with porous particles,
Phase 2: fluidizing the porous particles with at least one inner gas as fluidizing gas and adjusting the temperature of the fluidized bed reactor to the temperature for the conversion in phase 3,
Phase 3: fluidizing with at least one inner gas as fluidizing gas with addition of reactive gas containing one or more silicon precursors and converting the silicon precursors were deposition of silicon in pores and on the surface of the porous particles,
Phase 4: cooling the fluidized bed reactor and fluidizing with at least one inert gas as fluidizing gas, and/or
Phase 5: removing the reaction products from the fluidized bed reactor.

19. The process of claim 18, wherein during phases 2 to 4, the fluidized bed of the fluidized bed reactor has a coefficient of heat transfer a between any surface of a component within the fluidized bed and the fluidized bed itself, based on the maximum coefficient of heat transfer aₘₐₓ between any surface of a component within the fluidized bed and the fluidized bed itself of a/aₘₐₓ≥0.95.

20. The process of claim 18, wherein the temperature in phase 3 is in the range from 10 to 1000° C.

21. The process of claim 17, wherein the fluidizing gases contain inert constituents selected from the group comprising hydrogen, helium, nitrogen, neon, argon, krypton, xenon and carbon dioxide, in an amount of at least 50%, based on the partial pressure of the inert constituents, of the total pressure of the fluidizing gas.

22. The process of claim 18, wherein phase 3 is conducted with fluidizing gas streams with superficial velocities above the measured minimum fluidization velocity of the pulsed gas stream.

23. The process of claim 18, wherein the ratio of pulse fluidizing gas stream to overall fluidizing gas stream in the fluidized bed reactor during phases 2 to 4 is in the range from 0.1 to 1.

24. The process of claim 18, wherein during phase 3, a portion of the particles that form the fluidized bed is discharged and replaced by porous particles.

25. The process of claim 18, wherein the sequence of phases 2, 3 and optionally 4 is repeated at least once, optionally dispensing with phase 4 in one or more instances.

26. The process of claim 25, wherein a fluidizing gas containing at least one hydrocarbon and no silicon precursor is used during at least one of the repetitions of phase 3.
